(19) United States
(12) Patent Application Publication
(10) Pub. No.: US 2012/0129285 A1
(43) Pub. Date: May 24, 2012

(54) METHODS FOR MANUFACTURING DISPLAY PANEL AND DISPLAY APPARATUS

(75) Inventors: CHENGMING HE, Shenzhen (CN); WEI-CHUN LEE, Shenzhen (CN); BING-JEI LIAO, Shenzhen (CN)

(73) Assignee: Shenzhen China Star Optoelectronics Technology Co., LTD., Shenzhen City (CN)

(21) Appl. No.: 13/219,691

(22) Filed: Aug. 28, 2011

(30) Foreign Application Priority Data
Nov. 23, 2010 (CN) 201010557607.1

(51) Int. Cl. H01L 33/08

(52) U.S. Cl. 438/30; 257/E33.012

(57) ABSTRACT

The present invention provides methods for manufacturing a display panel and a display apparatus. The method comprises the following steps: sputtering alignment layers on substrates; forming a liquid crystal layer between the alignment layers to form a liquid crystal cell; applying a voltage to the liquid crystal cell; irradiating an ultraviolet light to the liquid crystal cell; and arranging the display panel on a backlight module. The invention can improve the quality of alignment films of the liquid crystal display panel.

### FIELD OF THE INVENTION

The present invention relates to a field of a liquid crystal display technology, and more particularly to methods for manufacturing a display panel and a display apparatus.

### BACKGROUND OF THE INVENTION

Liquid crystal displays (LCDs) have been widely applied in electrical products. Currently, most of LCDs are backlight type LCDs which comprise a liquid crystal panel and a backlight module. The liquid crystal panel is composed of two transparent substrates and a liquid crystal sealed there-between. In particular, a liquid crystal panel with a multi-domain alignment, which is made using a polymer-stabilized alignment (PSA) process, can have some advantages, such as wide view angle, high aperture ratio, high contrast and simple process.

In the PSA process, reactive monomers can be doped in the liquid crystal between the two transparent substrates and mixed with liquid crystal molecules, wherein the a polyimide (PI) is coated on the surface of each of the transparent substrates to be an alignment substrate. Subsequently, when applying a voltage and irradiating an ultraviolet (UV) light to the two transparent substrates, a phase separation occurs in the reactive monomers and the liquid crystal molecules, and a polymer is formed on the alignment substrate of the transparent substrate. The liquid crystal molecules are oriented along a direction of the polymer due to the interaction between the polymer and the liquid crystal molecules. Therefore, the liquid crystal molecules between the transparent substrates can have a pre-tile angle.

However, the coating process (such as inkjet printing) for the alignment substrate (PI) is susceptible to have some defects, such as pin holes or coating mura. Furthermore, the coated PI needs to be cured and is susceptible to adsorb water vapor. Accordingly, it is difficult to manage the quality of the alignment substrate, and the process yield of the display panel is deteriorated.

As a result, it is necessary to provide methods for manufacturing a liquid crystal display panel and a liquid crystal display apparatus to solve the problems existing in the conventional technologies, as described above.

### SUMMARY OF THE INVENTION

A primary object of the present invention is to provide a method for manufacturing a display panel, and the method comprises the following steps: sputtering a first alignment layer on a first substrate; sputtering a second alignment layer on a second substrate; forming a liquid crystal layer between the first alignment layer and the second alignment layer to form a liquid crystal cell, wherein the liquid crystal layer includes reactive monomers and liquid crystal molecules; applying a voltage to the liquid crystal cell to allow at least a portion of the reactive monomers and at least a portion of the liquid crystal molecules to be oriented along an alignment direction; and irradiating an ultraviolet light to the liquid crystal cell to allow the reactive monomers to bond with the first alignment layer and the second alignment layer, respectively.

Another object of the present invention is to provide a method for manufacturing a display panel, and the method comprises the following steps: sputtering a first alignment layer on a first substrate; sputtering a second alignment layer on a second substrate; forming a liquid crystal layer between the first alignment layer and the second alignment layer to form a liquid crystal cell, wherein the liquid crystal layer includes reactive monomers and liquid crystal molecules; applying a voltage to the liquid crystal cell to allow at least a portion of the reactive monomers and at least a portion of the liquid crystal molecules to be oriented along an alignment direction and have a pre-tile angle, wherein the pre-tile angle is less than 60 degrees; irradiating an ultraviolet light to the liquid crystal cell to allow the reactive monomers to bond with the first alignment layer and the second alignment layer, respectively; and removing the irradiated ultraviolet light and the applied voltage.

A further object of the present invention is to provide a method for manufacturing a display apparatus, the method comprises the following steps: sputtering a first alignment layer on a first substrate; sputtering a second alignment layer on a second substrate; forming a liquid crystal layer between the first alignment layer and the second alignment layer to form a liquid crystal cell, wherein the liquid crystal layer includes reactive monomers and liquid crystal molecules; applying a voltage to the liquid crystal cell to allow at least a portion of the reactive monomers and at least a portion of the liquid crystal molecules to be oriented along an alignment direction; and irradiating an ultraviolet light to the liquid crystal cell to allow the reactive monomers to bond with the first alignment layer and the second alignment layer, respectively; and arranging the display panel on a backlight module.

In one embodiment of the present invention, the material of the alignment layers is a dielectric and inorganic material.

In one embodiment of the present invention, the material of the alignment layers is SiO₂.

In one embodiment of the present invention, the method further comprises the following steps: forming a first electrode on the first substrate; and forming a second electrode on the second substrate, wherein the second electrode includes a plurality of regions.

In one embodiment of the present invention, the method further comprises the following steps: after irradiating the ultraviolet light, removing the irradiated ultraviolet light and the applied voltage.

In one embodiment of the present invention, the method further comprises the following steps: pre-cleaning and pre-curing the first substrate and the second substrate before the sputtering.

In one embodiment of the present invention, in the step of forming the liquid crystal layer, a liquid crystal of the liquid crystal layer is dispensed on the first substrate using a one-drop filling method, and the second substrate is aligned and assembled with the first substrate using an alignment assembly apparatus.

In one embodiment of the present invention, when removing the irradiated ultraviolet light and the applied voltage, the applied voltage is first removed, and then the irradiated ultraviolet is removed.

In comparison with the conventional alignment substrate whose quality is difficult to be managed, the methods for manufacturing the display panel and the display apparatus of the present invention can form the alignment substrate on the substrate using the sputtering technique, so as to enhance the film quality of alignment films of the display panel. Therefore, the invention can improve the quality and yield of the alignment layer of the display panel, thus further improving the quality and yield of the display apparatus comprising the same.

The structure and the technical means adopted by the present invention to achieve the above and other objects can be best understood by referring to the following detailed description of the preferred embodiments and the accompanying drawings.

### DESCRIPTION OF THE DRAWINGS

FIG. 1 is a cross-sectional view showing a display panel and a backlight module according to an embodiment of the present invention;

FIG. 2 is a partially cross-sectional view showing a display panel according to an embodiment of the present invention;

FIG. 3 is a partially cross-sectional view showing a display panel according to an embodiment of the present invention;

FIG. 4 is a partially cross-sectional view showing a display panel according to an embodiment of the present invention;

FIG. 5 is a partially cross-sectional view showing a display panel according to an embodiment of the present invention; and

FIG. 6 is a flow diagram showing a method for manufacturing the display panel according to an embodiment of the present invention.

### DETAILED DESCRIPTION OF THE PREFERRED EMBODIMENTS

The following embodiments are referring to the accompanying drawings for exemplifying specific implementable embodiments of the present invention. Furthermore, directional terms described by the present invention, such as upper, lower, front, back, left, right, inner, outer, side and etc., are only directions by referring to the accompanying drawings, and thus the used directional terms are used to describe and understand the present invention, but the present invention is not limited thereto.

In the drawings, structure-like elements are labeled with like reference numerals.

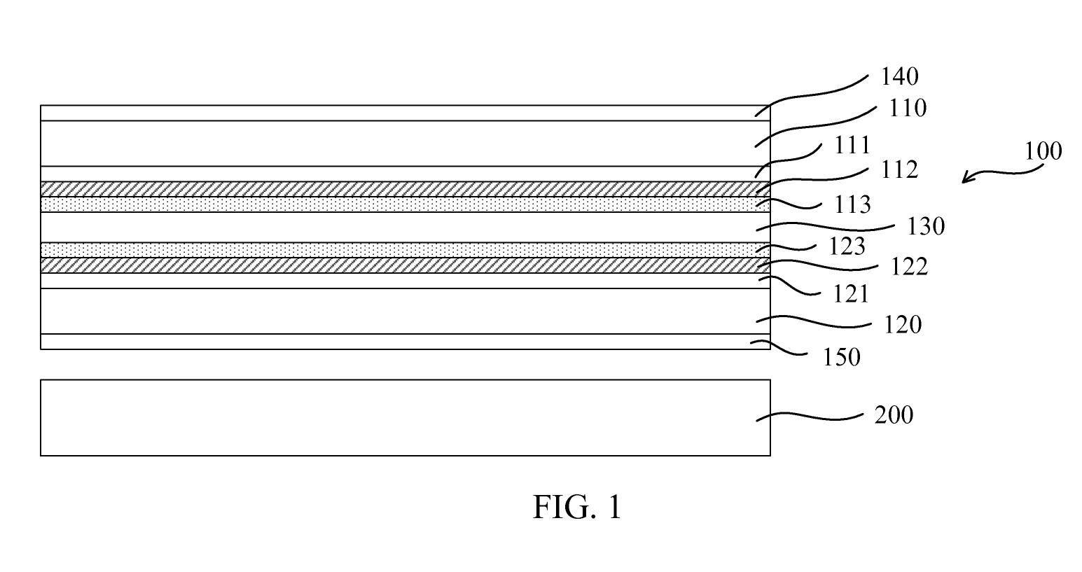

Referring to FIG. 1, a cross-sectional view showing a display panel and a backlight module according to an embodiment of the present invention is illustrated. The liquid crystal display apparatus of the present embodiment can comprises the liquid crystal display panel 100 and the backlight module 200. The liquid crystal display panel 100 is disposed opposite to the backlight module 200, and the backlight module 200 may be realized as an edge lighting backlight module or a bottom lighting backlight module to provide the liquid crystal display panel 100 with the back-light.

Referring to FIG. 1 again, the liquid crystal display panel 100 of the present embodiment may comprise a first substrate 110, a second substrate 120, a liquid crystal layer 130, a first polarizer 140 and a second polarizer 150. The first substrate 110 and the second substrate 120 may be realized as glass substrates or flexible plastic substrates. In this embodiment, the first substrate 110 may be a glass substrate or other material substrate with color filters (CF), and the second substrate 120 may be a glass substrate or other material substrate with a thin film transistor (TFT) array. It notes that the CF and the TFT array may also be disposed on the same substrate in other embodiments.

Referring to FIG. 1 again, the liquid crystal layer 130 is formed between the first substrate 110 and the second substrate 120 and includes reactive monomers 101 and liquid crystal molecules 102. The reactive monomers 101 are preferably photo-sensitive monomers mixed with the liquid crystal molecules 102. The first polarizer 140 is disposed on one side of the first substrate 110 and opposite to the liquid crystal layer 130 (as a light-emitting side). The second polarizer 150 is disposed on one side of the second substrate 120 and opposite to the liquid crystal layer 130 (as a light-incident side).

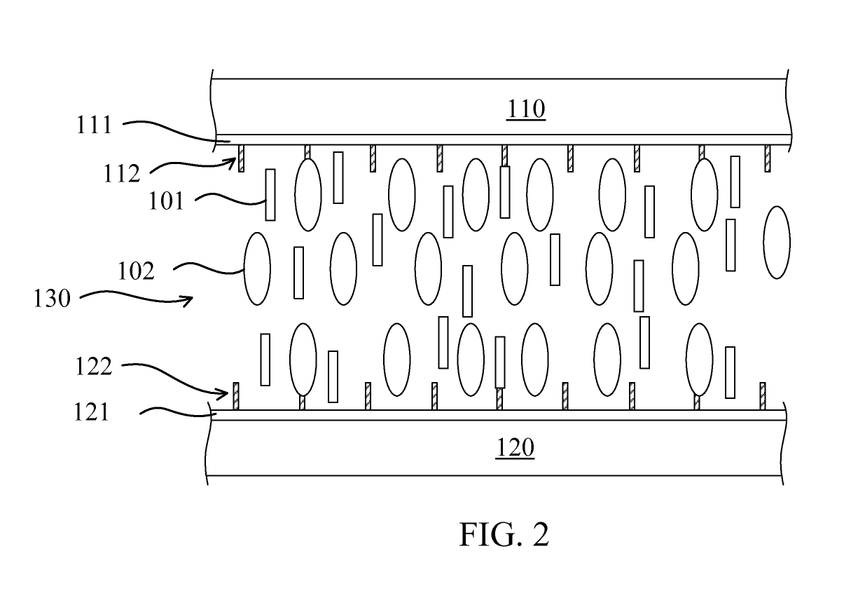

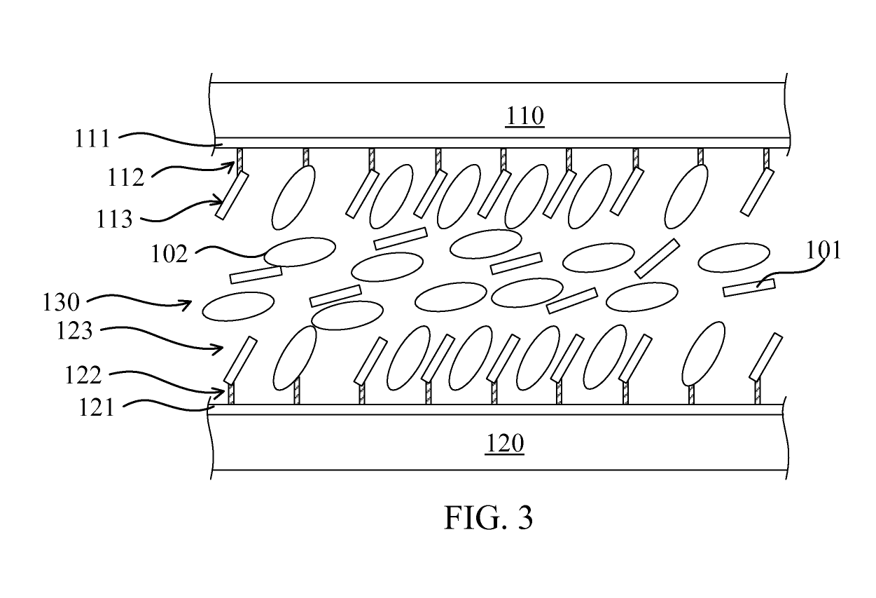

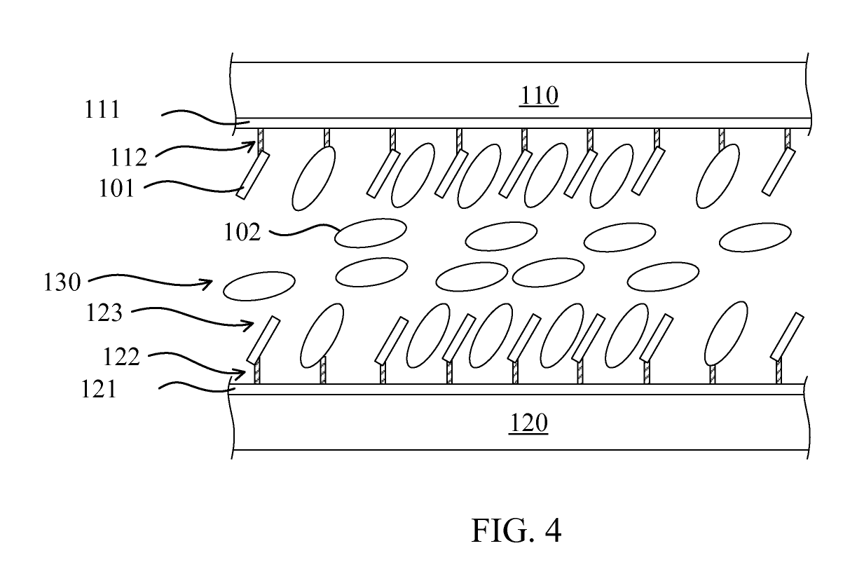

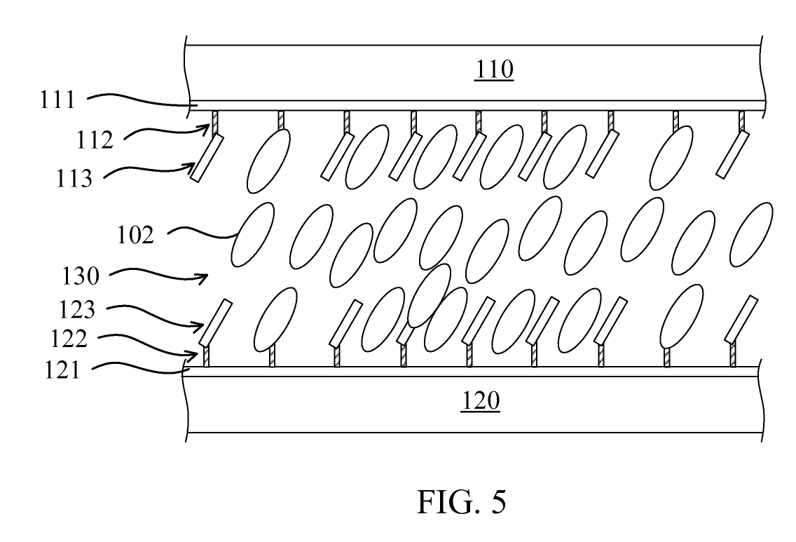

Referring to FIG. 2, FIG. 3, FIG. 4 and FIG. 5, partially cross-sectional views showing a display panel according to an embodiment of the present invention are illustrated. In this embodiment, the first substrate 110 can comprise a first electrode 111, a first alignment layer 112 and a first polymer alignment layer 113. The first alignment layer 112 and the first polymer alignment layer 113 are formed on the first electrode 111 in sequence. The second substrate 120 can comprise a second electrode 121, a second alignment layer 122 and a second polymer alignment layer 123. The second alignment layer 122 and the second polymer alignment layer 123 are formed on the second electrode 121 in sequence. The first electrode 111 and the second electrode 121 are preferably made of a transparent and electrically conductive material, such as ITO, IZO, AZO, GZO, TCO or ZnO. A voltage can be applied to the liquid crystal molecules 102 of the liquid crystal layer 130 by the first electrode 111 and the second electrode 121. In this embodiment, the first electrode 111 may be a common electrode, and the second electrode 121 may be a pixel electrode. In addition, the second electrode 121 can have a plurality of regions, and the voltage applied to each of the regions may be the same or different. The alignment layers 112, 122 and the polymer alignment layers 113, 123 can have an alignment direction for determining the orientation of the liquid crystal molecules of the liquid crystal layer 130. The alignment layers 112, 122 and the polymer alignment layers 113, 123 can have a pre-tile angle, wherein the pre-tile angle is less than 90 degrees, preferably less than 60 degrees. Preferably, the alignment layers 112, 122 are made of a dielectric material on the substrates 110, 120 using a sputtering technique. The material of the alignment layers 112, 122 is preferably a dielectric and inorganic material, such as silicon dioxide (SiO₂). The polymer alignment layers 113, 123 are polymerized of the reactive monomers 101 bonded with the alignment layers 112, 122.

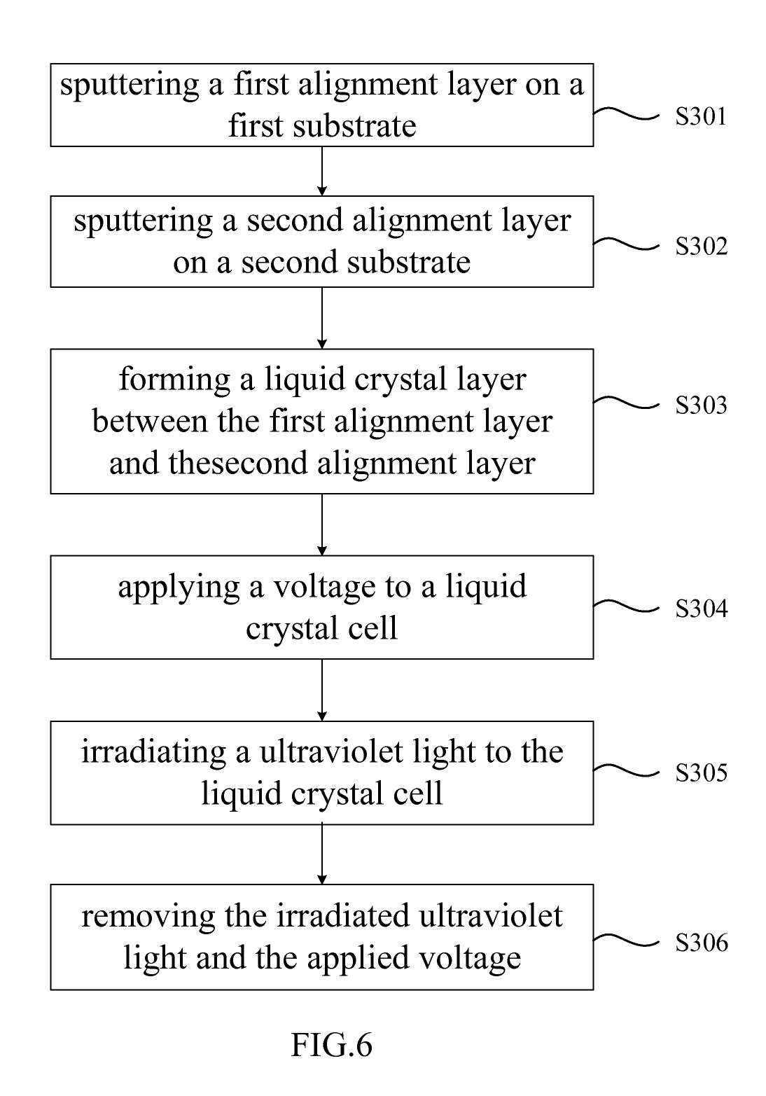

Referring to FIG. 2 and FIG. 6, FIG. 6 is a flow diagram showing a method for manufacturing the display panel according to an embodiment of the present invention. Firstly, the first alignment layer 112 is sputtered on the first substrate 110 (step S301), and the second alignment layer 122 is sputtered on the second substrate 120 (step S302). Before the steps S301 and S302, the first electrode 111 is formed on the first substrate 110, and the second electrode 121 is formed on the second substrate 120. Furthermore, before the steps S301 and S302, the substrates 110, 120 having the electrodes 111, 121 may be pre-cleaned and pre-cured, so as to clean the surfaces of the substrates 110, 120 (i.e. the surfaces of the electrodes 111, 121). In the steps S301 and S302, the dielectric material can be sputtered onto the electrodes 111, 121 of the substrates 110, 120, thereby forming the first alignment layer 112 and the second alignment layer 122.

Referring to FIG. 2 and FIG. 6 again, subsequently, the liquid crystal layer 130 is formed between the first alignment layer 112 of the first substrate 110 and the second alignment layer 122 of the second substrate 120 (step S303), thereby forming a liquid crystal cell, wherein the liquid crystal layer 130 includes the reactive monomers 101 with a small amount and the liquid crystal molecules 102. In the step S303, the liquid crystal of the liquid crystal layer 130 can be dispensed within the sealant (not shown) on the first substrate using, for example, a one-drop filling (ODF) method. Subsequently, the second substrate 120 can be aligned and assembled with the first substrate 110 using an alignment assembly apparatus, and the sealant is cured, thereby forming the liquid crystal layer 130 between the first substrate 110 and the second substrate 120.

Referring to FIG. 3 and FIG. 6 again, subsequently, a voltage is applied to the liquid crystal cell (step 304) to allow at least a portion of the reactive monomers 101 and at least a portion of the liquid crystal molecules 102 to be oriented along the alignment direction. With the voltage applied by the electrodes 111, 121, the liquid crystal molecules 102 can be rotated. At this time, the liquid crystal molecules 102 close to the alignment layers 112, 122 can be oriented along the predetermined alignment direction and have the pre-tile angle. Therefore, the reactive monomers 101 mixed with the liquid crystal molecules 102 can also be oriented along the predetermined alignment direction and have the pre-tile angle.

Referring to FIG. 4 and FIG. 6 again, subsequently, irradiating an ultraviolet light to the liquid crystal cell (step 305) to allow the reactive monomers 101 to bond with the first alignment layer 112 and the second alignment layer 122 and have the pre-tile angle, respectively. At this time, with the applied voltage and irradiated ultraviolet light, a phase separation occurs in the reactive monomers 101 and the liquid crystal molecules 102, and the reactive monomers 101 can be polymerized and react with the alignment layers 112, 122 of the substrates 110, 120 to form the polymer alignment layers 113, 123 on the alignment layers 112, 122, respectively, thereby forming the liquid crystal display panel 100. At this time, the alignment layers 112, 122 and the polymer alignment layers 113, 123 can have the predetermined alignment direction and the pre-tile angle. Therefore, the liquid crystal molecules 102 of the liquid crystal layer 130 can be oriented along the alignment direction provided by the alignment layers 112, 122 and the polymer alignment layers 113, 123, and have the pre-tile angle.

Referring to FIG. 5 and FIG. 6 again, after forming the polymer alignment layers 113, 123, the irradiated ultraviolet light and the applied voltage can be removed (step S306). It is worth mentioning that the applied voltage can be first removed, and then the irradiated ultraviolet is removed when removing the irradiated ultraviolet light and the applied voltage. Alternatively, the irradiated ultraviolet light and the applied voltage can be removed at the same time.

When the liquid crystal display panel 100 is applied to manufacture the display apparatus, the display panel 100 can be arranged on the backlight module 200, thereby forming the liquid crystal display apparatus, such as a display apparatus with multi-domain.

As described above, the methods for manufacturing the display panel and the display apparatus of the present invention can form the alignment substrate (the first alignment layer and the second alignment layer) on the substrate using the sputtering technique. The material of the first alignment layer and the second alignment layer can be the dielectric and inorganic material which is formed by using the sputtering technique, thereby enhancing the film quality of the first alignment layer and the second alignment layer and improving the problem that the quality of the conventional alignment substrate (PI) is difficult to be managed. Therefore, the methods for manufacturing the display panel and the display apparatus of the present invention can be applied to the PSA process and enhance the quality of the alignment substrate, so as to improve the quality and yield of the alignment layer (the alignment substrate and the polymer alignment layers), thus further improving the quality and yield of the display panel and the display apparatus.

The present invention has been described with a preferred embodiment thereof and it is understood that many changes and modifications to the described embodiment can be carried out without departing from the scope and the spirit of the invention that is intended to be limited only by the appended claims.

What is claimed is:

1. A method for manufacturing a display panel, wherein the method comprises the following steps:
sputtering a first alignment layer on a first substrate;
sputtering a second alignment layer on a second substrate;
forming a liquid crystal layer between the first alignment layer and the second alignment layer to form a liquid crystal cell, wherein the liquid crystal layer includes reactive monomers and liquid crystal molecules;
applying a voltage to the liquid crystal cell to allow at least a portion of the reactive monomers and at least a portion of the liquid crystal molecules to be oriented along an alignment direction and have a pre-tile angle, wherein the pre-tile angle is less than 60 degrees;
irradiating an ultraviolet light to the liquid crystal cell to allow the reactive monomers to bond with the first alignment layer and the second alignment layer, respectively; and
removing the irradiated ultraviolet light and the applied voltage.

2. A method for manufacturing a display panel, wherein the method comprises the following steps:
sputtering a first alignment layer on a first substrate;
sputtering a second alignment layer on a second substrate;
forming a liquid crystal layer between the first alignment layer and the second alignment layer to form a liquid crystal cell, wherein the liquid crystal layer includes reactive monomers and liquid crystal molecules;
applying a voltage to the liquid crystal cell to allow at least a portion of the reactive monomers and at least a portion of the liquid crystal molecules to be oriented along an alignment direction; and
irradiating an ultraviolet light to the liquid crystal cell to allow the reactive monomers to bond with the first alignment layer and the second alignment layer, respectively.

3. The method according to claim 2, wherein the material of the alignment layers is a dielectric and inorganic material.

4. The method according to claim 3, wherein the material of the alignment layers is SiO₂.

5. The method according to claim 2, wherein the method further comprises the following steps:
forming a first electrode on the first substrate; and
forming a second electrode on the second substrate, wherein the second electrode includes a plurality of regions.

6. The method according to claim 2, wherein the method further comprises the following steps:
after irradiating the ultraviolet light, removing the irradiated ultraviolet light and the applied voltage.

7. The method according to claim 2, wherein the method further comprises the following steps:
pre-cleaning and pre-curing the first substrate and the second substrate before the sputtering.

8. The method according to claim 2, wherein in the step of forming the liquid crystal layer, a liquid crystal of the liquid crystal layer is dispensed on the first substrate using a one-drop filling method, and the second substrate is aligned and assembled with the first substrate using an alignment assembly apparatus.

9. The method according to claim 2, wherein when removing the irradiated ultraviolet light and the applied voltage, the applied voltage is first removed, and then the irradiated ultraviolet is removed.

10. The method according to claim 2, wherein when removing the irradiated ultraviolet light and the applied voltage, the irradiated ultraviolet light and the applied voltage are removed at the same time.

11. A method for manufacturing a display apparatus, wherein the method comprises the following steps:
sputtering a first alignment layer on a first substrate;
sputtering a second alignment layer on a second substrate;
forming a liquid crystal layer between the first alignment layer and the second alignment layer to form a liquid crystal cell, wherein the liquid crystal layer includes reactive monomers and liquid crystal molecules;
applying a voltage to the liquid crystal cell to allow at least a portion of the reactive monomers and at least a portion of the liquid crystal molecules to be oriented along an alignment direction;
irradiating an ultraviolet light to the liquid crystal cell to allow the reactive monomers to bond with the first alignment layer and the second alignment layer, respectively; and
arranging the display panel on a backlight module.

12. The method according to claim 11, wherein the material of the alignment layers is a dielectric and inorganic material.

13. The method according to claim 12, wherein the material of the alignment layers is SiO₂.

14. The method according to claim 11, wherein the method further comprises the following steps:
forming a first electrode on the first substrate; and
forming a second electrode on the second substrate, wherein the second electrode includes a plurality of regions.

15. The method according to claim 11, wherein the method further comprises the following steps:
after irradiating the ultraviolet light, removing the irradiated ultraviolet light and the applied voltage.

16. The method according to claim 11, wherein the method further comprises the following steps:
pre-cleaning and pre-curing the first substrate and the second substrate before the sputtering.

17. The method according to claim 11, wherein in the step of forming the liquid crystal layer, a liquid crystal of the liquid crystal layer is dispensed on the first substrate using a one-drop filling method, and the second substrate is aligned and assembled with the first substrate using an alignment assembly apparatus.

18. The method according to claim 11, wherein when removing the irradiated ultraviolet light and the applied voltage, the applied voltage is first removed, and then the irradiated ultraviolet is removed.

19. The method according to claim 11, wherein when removing the irradiated ultraviolet light and the applied voltage, the irradiated ultraviolet light and the applied voltage are removed at the same time.
